(19) United States
(12) Patent Application Publication
(10) Pub. No.: US 2024/0268237 A1
(43) Pub. Date: Aug. 8, 2024

(54) MAGNETIC DOMAIN WALL MOTION ELEMENT AND MAGNETIC ARRAY

(71) Applicant: TDK CORPORATION, Tokyo (JP)

(72) Inventors: Minoru OTA, Tokyo (JP); Tatsuo SHIBATA, Tokyo (JP)

(73) Assignee: TDK CORPORATION, Tokyo (JP)

(21) Appl. No.: 18/294,338

(22) PCT Filed: Aug. 3, 2021
(86) PCT No.: PCT/JP2021/028764

§ 371 Date: Apr. 19, 2024

(51) Int. Cl. H10N 50/10; H10B 61/00

(52) U.S. Cl. CPC H10N 50/10; H10B 61/00

(57) ABSTRACT

A magnetic domain wall motion element includes a magnetic domain wall motion layer in which a magnetic domain wall is formed, a ferromagnetic layer, and a nonmagnetic layer interposed between the magnetic domain wall motion layer and the ferromagnetic layer, wherein at least a portion of a first surface of the magnetic domain wall motion layer on a side closer to the ferromagnetic layer, at a position overlapping with the ferromagnetic layer in a plan view in a laminating direction, is curved.

### TECHNICAL FIELD

The present invention relates to a magnetic domain wall motion element and a magnetic array.

### BACKGROUND ART

Next generation nonvolatile memories are attracting attention as an alternative to flash memories, which have reached their limits in miniaturization. For example, magnetoresistive random access memories (MRAMs), resistive random access memories (ReRAMs), phase change random access memories (PCRAMs), and the like are known as next-generation nonvolatile memories.

An MRAM has a magnetoresistive effect element whose resistance value changes depending on a change in a magnetization direction. A magnetic domain wall motion element is one aspect of a magnetoresistive effect element. For example, as described in Patent Document 1, since a magnetic domain wall motion element has a resistance value that changes depending on a position of a magnetic domain wall within a magnetic domain wall motion layer, it is expected to be used for multilevel recording and analog information processing is expected.

### CITATION LIST

### Patent Document

[Patent Document 1]
Japanese Patent No. 5441005

### SUMMARY OF INVENTION

### Technical Problem

There is a limit to a region that can be occupied by one magnetic domain wall motion element in order to improve integration of a magnetic array. There is a need for a magnetic domain wall motion element that can set a large number of gradations within a limited region.

The present invention has been made in view of the above problems, and an object thereof is to provide a magnetic domain wall motion element and a magnetic array that can set a large number of gradations.

### Solution to Problem

(1) A magnetic domain wall motion element according to a first aspect includes a magnetic domain wall motion layer in which a magnetic domain wall is formed, a ferromagnetic layer, and a nonmagnetic layer interposed between the magnetic domain wall motion layer and the ferromagnetic layer. At least a portion of a first surface of the magnetic domain wall motion layer on a side closer to the ferromagnetic layer, at a position overlapping with the ferromagnetic layer in a plan view in a laminating direction, is curved.
(2) In the magnetic domain wall motion element according to the above aspect, at least of a second surface of the magnetic domain wall motion layer on a side opposite to the first surface, at a position overlapping the ferromagnetic layer in a plan view in the laminating direction, may be curved.
(3) In the magnetic domain wall motion element according to the above aspect, the curved surface of the first surface may be curved in one direction.
(4) The magnetic domain wall motion element according to the above aspect may further include a first conductive layer and a second conductive layer each connected to the magnetic domain wall motion layer. The curved surface of the first surface may be curved in a first direction when a direction from the first conductive layer toward the magnetic domain wall motion layer in the laminating direction is defined as the first direction.
(5) The magnetic domain wall motion element according to the above aspect may further include a first conductive layer and a second conductive layer each connected to the magnetic domain wall motion layer. The curved surface of the first surface may be curved in a second direction when a direction from the first conductive layer toward the magnetic domain wall motion layer in the laminating direction is defined as a first direction and a direction opposite to the first direction is defined as the second direction.
(6) The magnetic domain wall motion element according to the above aspect may further include a first conductive layer and a second conductive layer each connected to the magnetic domain wall motion layer. A first connection surface between the first conductive layer and the magnetic domain wall motion layer may be at a different position in the laminating direction from a second connection surface between the second conductive layer and the magnetic domain wall motion layer.
(7) In the magnetic domain wall motion element according to the above aspect, a second surface of the magnetic domain wall motion layer on the side opposite to the first surface may include the first connection surface, the second connection surface, and the curved surface, and when a direction from the first conductive layer toward the magnetic domain wall motion layer in the laminating direction is defined as a first direction, an inflection point of the curved surface of the second surface may be located on the first direction side from positions of the first connection surface and the second connection surface in the laminating direction.
(8) In the magnetic domain wall motion element according to the above aspect, a second surface of the magnetic domain wall motion layer on the side opposite to the first surface may include the first connection surface, the second connection surface, and the curved surface, and when a direction from the first conductive layer to the magnetic domain wall motion layer in the laminating direction is defined as a first direction and a direction opposite to the first direction is defined as a second direction, an inflection point of the curved surface of the second surface may be located on the second direction side from positions of the first connection surface and the second connection surface in the laminating direction.
(9) The magnetic domain wall motion element according to the above aspect may further include a first conductive layer and a second conductive layer each connected to the magnetic domain wall motion layer. A part of the first conductive layer may protrude toward the second conductive layer from a first connection surface between the first conductive layer and the magnetic domain wall motion layer when viewed in the laminating direction.
(10) The magnetic domain wall motion element according to the above aspect may further include a first conductive layer and a second conductive layer each connected to the magnetic domain wall motion layer, a first insulating layer located between the first conductive layer and the second conductive layer, and a second insulating layer in contact with a surface of the first insulating layer on a side opposite to a surface in contact with the magnetic domain wall motion layer, wherein the first insulating layer has higher thermal conductivity than the second insulating layer.
(11) A magnetic array according to a second aspect includes a plurality of magnetic domain wall motion elements according to the above aspect.

### Advantageous Effects of Invention

The magnetic domain wall motion element and the magnetic array according to the above aspects can set a large number of gradations.

### BRIEF DESCRIPTION OF DRAWINGS

FIG. 1 is a configuration diagram of a magnetic array according to a first embodiment.

FIG. 2 is a cross-sectional view of a featured portion of the magnetic array according to the first embodiment.

FIG. 3 is a cross-sectional view of a magnetic domain wall motion element according to the first embodiment.

FIG. 4 is a plan view of the magnetic domain wall motion element according to the first embodiment.

FIG. 5 is a cross-sectional view of a magnetic domain wall motion element according to a second embodiment.

FIG. 6 is a cross-sectional view of a magnetic domain wall motion element according to a third embodiment.

FIG. 7 is a cross-sectional view of a magnetic domain wall motion element according to a fourth embodiment.

FIG. 8 is a cross-sectional view of a magnetic domain wall motion element according to a fifth embodiment.

FIG. 9 is a cross-sectional view of a magnetic domain wall motion element according to a sixth embodiment.

FIG. 10 is a cross-sectional view of a magnetic domain wall motion element according to a seventh embodiment.

FIG. 11 is a cross-sectional view of a magnetic domain wall motion element according to an eighth embodiment.

FIG. 12 is a cross-sectional view of a magnetic domain wall motion element according to a ninth embodiment.

FIG. 13 is a cross-sectional view of a magnetic domain wall motion element according to a tenth embodiment.

FIG. 14 is a cross-sectional view of a magnetic domain wall motion element according to an eleventh embodiment.

FIG. 15 is a cross-sectional view of a magnetic domain wall motion element according to a twelfth embodiment.

FIG. 16 is a cross-sectional view of a magnetic domain wall motion element according to a thirteenth embodiment.

FIG. 17 is a cross-sectional view of a magnetic domain wall motion element according to a fourteenth embodiment.

### DESCRIPTION OF EMBODIMENTS

The present embodiment will be described in detail below with reference to the drawings as appropriate. In the figures used in the following description, in order to make features of the present invention easier to understand, featured portions thereof may be shown enlarged for convenience, and dimensional ratios or the like of each constituent element may differ from actual ones. Materials, dimensions, and the like exemplified in the following description are examples, and the present invention is not limited thereto and can be implemented with appropriate changes within the scope of achieving the effects of the present invention.

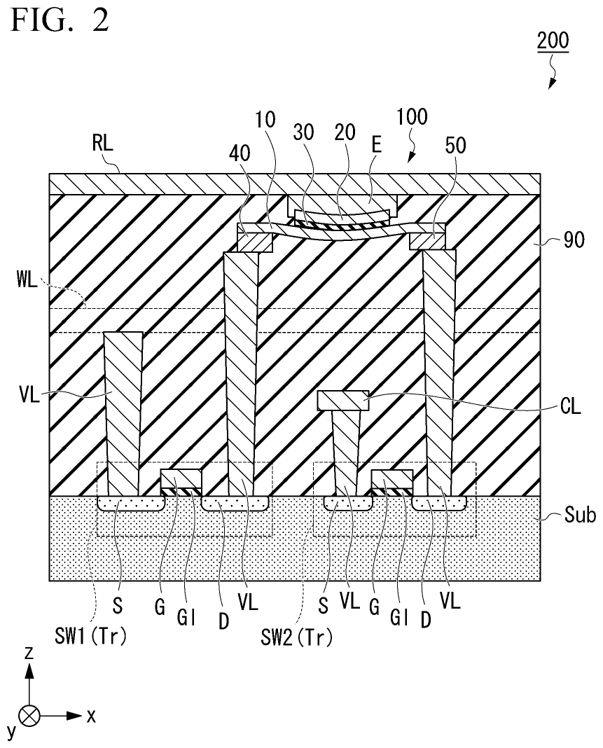

First, directions will be defined. An x direction and a y direction are directions substantially parallel to one surface of a substrate Sub (see FIG. 2), which will be described later. The x direction is a direction in which a magnetic domain wall motion layer 10 extends, which will be described later. The y direction is a direction orthogonal to the x direction. A z direction is a laminating direction of each layer of the magnetic domain wall motion element. Hereinafter, a direction from the substrate Sub to the magnetic domain wall motion element will be referred to as a +z direction, and a direction opposite thereto will be referred to as a −z direction. Although the +z direction is sometimes expressed as “upward” and the −z direction is sometimes expressed as “downward,” these expressions are for convenience and do not define the direction of gravity.

### First Embodiment

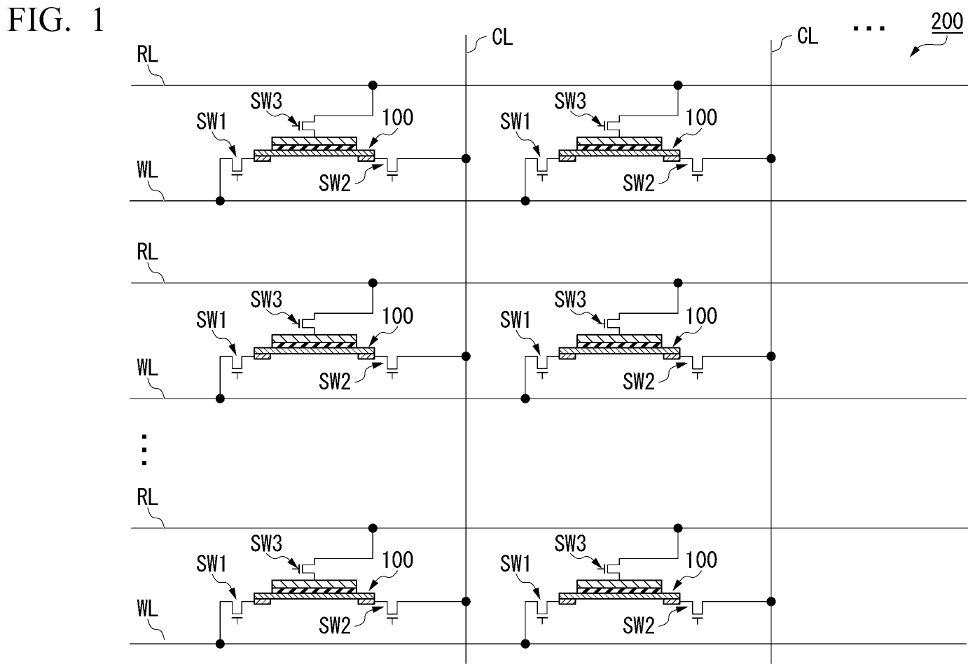

FIG. 1 is a configuration diagram of a magnetic array 200 according to a first embodiment. The magnetic array 200 includes a plurality of magnetic domain wall motion elements 100, a plurality of first wirings WL, a plurality of second wirings CL, a plurality of third wirings RL, a plurality of first switching elements SW1, a plurality of second switching elements SW2, and a plurality of third switching elements SW3. For example, the magnetic array 200 can be used for magnetic memories, product-sum operators, neuromorphic devices, spin memristors, and magneto-optical elements.

Each of the first wirings WL is a write wiring. Each of the first wirings WL electrically connects a power source to one or more magnetic domain wall motion elements 100. The power source is connected to one end of the magnetic array 200 in use.

Each of the second wirings CL is a common wiring. A common wiring is a wiring that can be used both when writing and reading data. Each of the second wirings CL electrically connects a reference potential to one or more magnetic domain wall motion elements 100. The reference potential is, for example, ground. One second wiring CL may be connected to only one magnetic domain wall motion element 100 or may be connected across a plurality of magnetic domain wall motion elements 100.

Each of the third wirings RL is a readout wiring. Each of the third wirings RL electrically connects a power source to one or more magnetic domain wall motion elements 100. The power source is connected to one end of the magnetic array 200 in use.

In FIG. 1, the first switching element SW1, the second switching element SW2, and the third switching element SW3 are connected to each of the plurality of magnetic domain wall motion elements 100. The first switching element SW1 is connected between the magnetic domain wall motion element 100 and the first wiring WL. The second switching element SW2 is connected between the magnetic domain wall motion element 100 and the second wiring CL. The third switching element SW3 is connected between the magnetic domain wall motion element 100 and the third wiring RL.

When the first switching element SW1 and the second switching element SW2 connected to a predetermined magnetic domain wall motion element 100 are turned on, a write current flows through the predetermined magnetic domain wall motion element 100. When the second switching element SW2 and the third switching element SW3 connected to a predetermined magnetic domain wall motion element 100 are turned on, a read current flows through the predetermined magnetic domain wall motion element 100.

The first switching element SW1, the second switching element SW2, and the third switching element SW3 are elements each controlling a current flow. Each of the first switching element SW1, the second switching element SW2, and the third switching element SW3 is, for example, a transistor, an element utilizing a phase change in a crystal layer, such as an ovonic threshold switch (OTS), an element utilizing a change in a band structure, such as a metal-insulator transition (MIT) switch, an element utilizing a breakdown voltage, such as a Zener diode or an avalanche diode, or an element whose conductivity changes as an atomic position changes.

Any of the first switching element SW1, the second switching element SW2, and the third switching element SW3 may be shared by the magnetic domain wall motion element 100 connected to the same wiring. For example, in a case in which the first switching element SW1 is shared, one first switching element SW1 is provided upstream in (on one end of) the first wiring WL. For example, in a case in which the second switching element SW2 is shared, one second switching element SW2 is provided upstream in (on one end of) the second wiring CL. For example, in a case in which the third switching element SW3 is shared, one third switching element SW3 is provided upstream in (on one end of) the third wiring RL.

FIG. 2 is a cross-sectional view of a featured portion of the magnetic array 200 according to the first embodiment. FIG. 2 is a cross-section of one magnetic domain wall motion element 100 in FIG. 1 along an xz plane passing through a center of a width of the magnetic domain wall motion layer 10 in the y direction.

The first switching element SW1 and the second switching element SW2 shown in FIG. 2 are transistors Tr. The transistor Tr includes a gate electrode G, a gate insulating film GI, and a source S and a drain D formed on a substrate Sub. The source S and the drain D are determined depending on a current flow direction, and a positional relationship thereof may be reversed. The substrate Sub is, for example, a semiconductor substrate. The third switching element SW3 is electrically connected to the third wiring RL and is located at a position deviated in the x direction in FIG. 2, for example.

The transistors Tr and the magnetic domain wall motion element 100 are connected to each other via a wiring VL. The wiring VL extends in the z direction. The wiring VL is sometimes called a via wiring. The first wiring WL and the transistor Tr, and the second wiring CL and the transistor Tr are connected to each other via the wiring VL. The wiring VL is formed, for example, in holes formed in an insulating layer 90. The magnetic domain wall motion element 100 and the third wiring RL are connected to each other via an electrode E.

The insulating layer 90 is an insulating layer that insulates between wirings of multilayer wiring and between elements. The magnetic domain wall motion element 100 and the transistors Tr are electrically separated by the insulating layer 90 except for the wiring VL. The insulating layer 90 is made of, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide. (ZrOₓ), or the like.

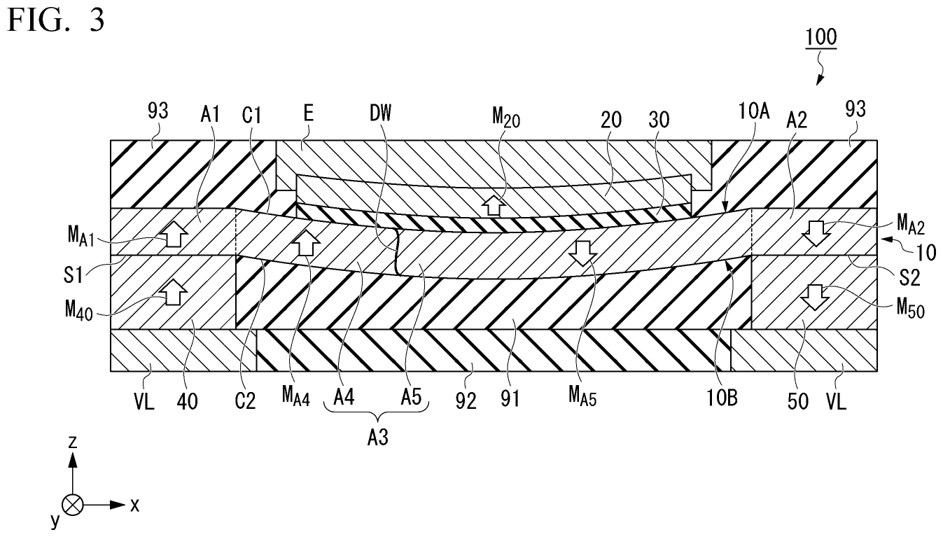

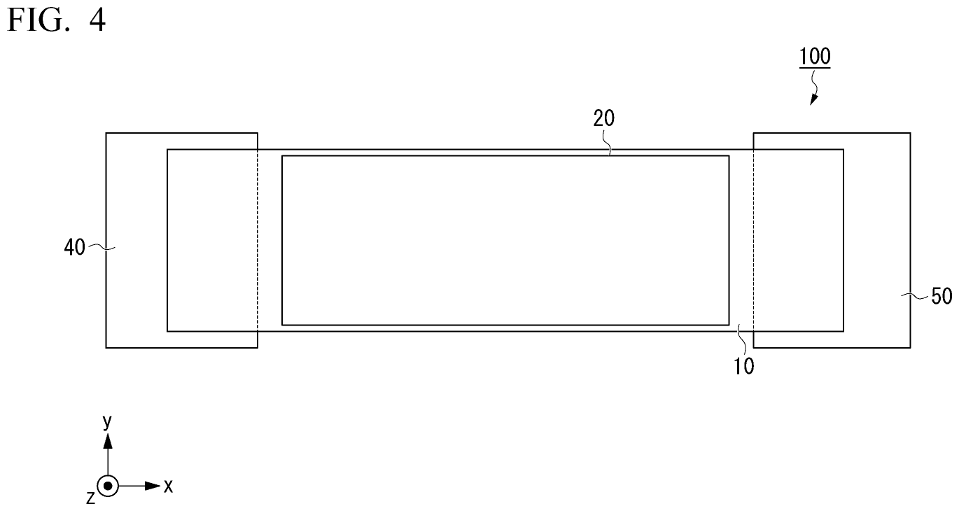

FIG. 3 is a cross-sectional view of the magnetic domain wall motion element 100 along the xz plane passing through the center of the magnetic domain wall motion layer 10 in the y direction. FIG. 4 is a plan view of the magnetic domain wall motion element 100 in a plan view in the z direction. Arrows shown in the figure are examples of orientation directions of magnetization of a ferromagnetic material.

The magnetic domain wall motion element 100 includes, for example, the magnetic domain wall motion layer 10, a ferromagnetic layer 20, a nonmagnetic layer 30, a conductive layer 40, and a conductive layer 50. The conductive layer 40 is an example of a first conductive layer. The conductive layer 50 is an example of a second conductive layer.

At the time of writing data to the magnetic domain wall motion element 100, a current is passed between the conductive layer 40 and the conductive layer 50 along the magnetic domain wall motion layer 10. At the time of reading out data from the magnetic domain wall motion element 100, a current is passed between the electrode E and at least one of the conductive layer 40 and the conductive layer 50.

The magnetic domain wall motion layer 10 extends in the x direction. The magnetic domain wall motion layer 10 has a plurality of magnetic domains therein and has a magnetic domain wall DW at a boundary between the plurality of magnetic domains. The magnetic domain wall motion layer 10 is, for example, a layer in which information can be magnetically recorded by changing its magnetic state. The magnetic domain wall motion layer 10 is sometimes called an analog layer or a magnetic recording layer.

The magnetic domain wall motion layer 10 is curved. The magnetic domain wall motion layer 10 is curved in the −z direction. In FIG. 3, the −z direction is a direction opposite to a direction from the conductive layer 40 toward the magnetic domain wall motion layer 10 and is an example of a “second direction.” A center portion of the magnetic domain wall motion layer 10 in the x direction protrudes from end portions thereof in the −z direction of the z direction. When a distance between the conductive layers 40 and 50 and a center of the magnetic domain wall motion layer 10 in the x direction is short, heat generated in the magnetic domain wall motion layer 10 can be efficiently exhausted.

A first surface 10A of the magnetic domain wall motion layer 10 is curved at at least a portion of a position overlapping the ferromagnetic layer 20 when viewed in the z direction. The first surface 10A is a surface of the magnetic domain wall motion layer 10 on the ferromagnetic layer 20 side. A curved portion of the first surface 10A is referred to as a curved surface C1. The curved surface C1 is located at a position overlapping the ferromagnetic layer 20 when viewed in the z direction. The curved surface C1 is located in a third region A3, for example. The curved surface C1 curves in the −z direction. The curved surface C1 has one inflection point in a xz cross-section. The inflection point of the curved surface C1 is located on the −z direction side from end portions of the first surface 10A.

A second surface 10B of the magnetic domain wall motion layer 10 is curved at at least a portion of a position overlapping the ferromagnetic layer 20 when viewed in the z direction. The second surface 10B is a surface of the magnetic domain wall motion layer 10 on a side opposite to the first surface 10A. A curved portion of the second surface 10B is referred to as a curved surface C2. The curved surface C2 is located at a position overlapping the ferromagnetic layer 20 when viewed in the z direction. The curved surface C2 curves in the same direction (−z direction) as the curved surface C1. The curved surface C2 has one inflection point in the xz cross-section. The inflection point of the curved surface C2 is located on the −z direction side from connection surfaces S1 and S2. The connection surface S1 is a connection surface between the conductive layer 40 and the magnetic domain wall motion layer 10, and the connection surface S2 is a connection surface between the conductive layer 50 and the magnetic domain wall motion layer 10.

A thickness of the magnetic domain wall motion layer 10 is substantially constant. “Substantially constant” indicates that, when measurements are taken at 10 different points in the x direction, all deviations from an average thickness of the 10 measured points are within 10%. When the thickness of the magnetic domain wall motion layer 10 is substantially constant, a current density of a current flowing therein is substantially constant, and a moving speed of the magnetic domain wall DW is substantially constant. The moving speed of the magnetic domain wall DW becomes more constant, linearity of a change in a resistance value of the magnetic domain wall motion element 100 increases.

The magnetic domain wall motion layer 10 includes a first region A1, a second region A2, and a third region A3. The first region A1 is a region overlapping the conductive layer 40 when viewed in the z direction. The second region A2 is a region overlapping the conductive layer 50 when viewed in the z direction. The third region A3 is a region other than the first region A1 and the second region A2 of the magnetic domain wall motion layer 10. The third region A3 is, for example, a region interposed between the first region A1 and the second region A2 in the x direction.

Magnetization M_{A1} of the first region A1 is fixed, for example, by magnetization M₄₀ of the conductive layer 40. Magnetization M_{A2} of the second region A2 is fixed, for example, by magnetization M₅₀ of the conductive layer 50. The fact that magnetization is fixed indicates that magnetization is not reversed during a normal operation of the magnetic domain wall motion element 100 (no external force beyond expectations is applied). For example, the first region A1 and the second region A2 have opposite orientation directions of magnetization.

The third region A3 is a region in which a magnetization direction changes and the magnetic domain wall DW can move. The third region A3 includes a first magnetic domain A4 and a second magnetic domain A5. The first magnetic domain A4 and the second magnetic domain A5 have opposite orientation directions of magnetization. A boundary between the first magnetic domain A4 and the second magnetic domain A5 is the magnetic domain wall DW. Magnetization M_{A4} of the first magnetic domain A4 is, for example, oriented in the same direction as the magnetization M_{A1} of the first region A1. Magnetization of the second magnetic domain A5 is, for example, oriented in the same direction as the magnetization M_{A2} of the adjacent second region A2. In principle, the magnetic domain wall DW moves in the third region A3 and does not invade the first region A1 and the second region A2.

When a proportion between the first magnetic domain A4 and the second magnetic domain A5 in the third region A3 changes, the magnetic domain wall DW moves. The magnetic domain wall DW is moved by flowing a write current in the x direction of the third region A3. For example, when a write current (for example, a current pulse) in the +x direction is applied to the third region A3, electrons flow in the −x direction opposite to the current, and thus the magnetic domain wall DW moves in the −x direction. When a current flows from the first magnetic domain A4 to the second magnetic domain A5, spin-polarized electrons in the second magnetic domain A5 reverse the magnetization of the first magnetic domain A4. By reversing the magnetization of the first magnetic domain A4, the magnetic domain wall DW moves in the −x direction.

The magnetic domain wall motion layer 10 includes, for example, a magnetic material. The magnetic domain wall motion layer 10 is, for example, a ferromagnetic material, a ferrimagnetic material, or a combination of these and an antiferromagnetic material. The magnetic domain wall motion layer 10 includes, for example, at least one element selected from the group consisting of Co, Ni, Fe, Pt, Pd, Gd, Tb, Mn, Ge, and Ga. The magnetic domain wall motion layer 10 is, for example, a laminated film of Co and Ni, a laminated film of Co and Pt, a laminated film of Co and Pd, a MnGa-based alloy, a GdCo-based alloy, a TbCo-based alloy, or the like. Ferrimagnetic materials such as a MnGa-based alloy, a GdCo-based alloy, and a TbCo-based alloy have small saturation magnetization, and a threshold current required to move the magnetic domain wall DW decreases. Further, a laminated film of Co and Ni, a laminated film of Co and Pt, and a laminated film of Co and Pd have a large coercive force, and the moving speed of the magnetic domain wall DW becomes slower. Examples of the antiferromagnetic material include Mn₃X (X is Sn, Ge, Ga, Pt, Ir, or the like), CuMnAs, Mn₂Au, and the like.

The ferromagnetic layer 20 is on the nonmagnetic layer 30. Magnetization M₂₀ of the ferromagnetic layer 20 is more difficult to reverse than the magnetizations M_{A4} and M_{A5} of the third region A3 of the magnetic domain wall motion layer 10. The magnetization M₂₀ of the ferromagnetic layer 20 is fixed without changing its direction when an external force enough to reverse the magnetization of the third region A3 is applied. The ferromagnetic layer 20 is sometimes called a reference layer or a pinned layer.

The ferromagnetic layer 20 is curved along the first surface 10A of the magnetic domain wall motion layer 10. The ferromagnetic layer 20 is curved in the −z direction. A thickness of the ferromagnetic layer 20 is substantially constant.

The ferromagnetic layer 20 includes a ferromagnetic material. The ferromagnetic layer 20 includes, for example, a material that easily obtains a coherent tunnel effect with the magnetic domain wall motion layer 10. The ferromagnetic layer 20 includes, for example, a metal selected from the group consisting of Cr, Mn, Co, Fe, and Ni, an alloy containing one or more of these metals, or an alloy containing these metals and at least one element of B, C, and N. The ferromagnetic layer 20 is made of, for example, Co—Fe, Co—Fe—B, or Ni—Fe.

The ferromagnetic layer 20 may be, for example, a Heusler alloy. A Heusler alloy is a half metal and has high spin polarizability. A Heusler alloy is an intermetallic compound with a chemical composition of XYZ or X₂YZ, in which X is Co, Fe, Ni, or a transition metal element or noble metal element of the Cu group on the periodic table, Y is Mn, V, Cr or a transition metal of the Ti group or an elemental species of X, and Z is a typical element from Group III to Group V. Examples of the Heusler alloy include Co₂FeSi, Co₂FeGe, Co₂FeGa, Co₂MnSi, CO₂Mn₁₋ₐFeₐAl_{b}Si_{1-b}, Co₂FeGe_{1-c}Ga_{c}, and the like.

In addition, the ferromagnetic layer 20 may have a synthetic structure including a ferromagnetic layer and a nonmagnetic layer, or a synthetic structure including an antiferromagnetic layer, a ferromagnetic layer, and a nonmagnetic layer. In the latter case, a magnetization direction of the ferromagnetic layer 20 is strongly held by the antiferromagnetic layer in the synthetic structure. For that reason, the magnetization of the ferromagnetic layer 20 is less susceptible to external influences. When the magnetization of the ferromagnetic layer 20 is oriented in the Z direction (the magnetization of the ferromagnetic layer 20 is made into a perpendicular magnetization film), it is preferable to further include, for example, a Co/Ni laminated film, a Co/Pt laminated film, or the like.

The nonmagnetic layer 30 is interposed between the magnetic domain wall motion layer 10 and the ferromagnetic layer 20. The nonmagnetic layer 30 is, for example, on the magnetic domain wall motion layer 10.

The nonmagnetic layer 30 is made of, for example, a nonmagnetic insulator, semiconductor, or metal. Examples of the nonmagnetic insulator include, for example, Al₂O₃, SiO₂, MgO, MgAl₂O₄, and a material in which a portion of Al, Si, or Mg is replaced with Zn, Be, or the like. These materials have a large band gap and excellent insulating properties. When the nonmagnetic layer 30 is made of a nonmagnetic insulator, the nonmagnetic layer 30 is a tunnel barrier layer. Examples of the nonmagnetic metal include Cu, Au, and Ag. Examples of the nonmagnetic semiconductor include Si, Ge, CuInSe₂, CuGaSe₂, Cu(In, Ga)Se₂, and the like.

The nonmagnetic layer 30 is curved along the first surface 10A of the magnetic domain wall motion layer 10. The nonmagnetic layer 30 is curved in the −z direction. A thickness of the nonmagnetic layer 30 is substantially constant.

The thickness of the nonmagnetic layer 30 is, for example, 20 Å or more, and may be 25 Å or more. When the thickness of the nonmagnetic layer 30 increases, a resistance area product (RA) of the magnetic domain wall motion element 100 becomes larger. The resistance area product (RA) of the magnetic domain wall motion element 100 is preferably 1×10⁴ Ωμm² or more, and more preferably 5×10⁴ Ωμm² or more. The resistance area product (RA) of the magnetic domain wall motion element 100 is expressed as a product of an element resistance of one magnetic domain wall motion element 100 and an element cross-sectional area of the magnetic domain wall motion element 100 (an area of a cross-section of the nonmagnetic layer 30 taken along the xy plane).

The conductive layer 40 is connected to the magnetic domain wall motion layer 10. The conductive layer 40 is connected via the connection surface S1. The conductive layer 40 connects the magnetic domain wall motion layer 10 to the wiring VL. The conductive layer 50 is connected to the magnetic domain wall motion layer 10 at a different position from the conductive layer 40. The conductive layer 50 is connected via the connection surface S2. The conductive layer 50 connects the magnetic domain wall motion layer 10 to the wiring VL. Other layers may be provided between the conductive layer 40 and the magnetic domain wall motion layer 10 or between the conductive layer 50 and the magnetic domain wall motion layer 10.

For example, the conductive layer 40 is connected to a first end of the magnetic domain wall motion layer 10, and the conductive layer 50 is connected to a second end of the magnetic domain wall motion layer 10. In a plan view in the z direction, the conductive layer 40 and the conductive layer 50 interpose the ferromagnetic layer 20 in the x direction. The conductive layer 40 and the conductive layer 50 may be connected to different surfaces of the magnetic domain wall motion layer 10.

The conductive layer 40 fixes the magnetization M_{A1} of the first region A1. The conductive layer 50 fixes the magnetization M_{A2} of the second region A2. The conductive layer 40 and the conductive layer 50 each contain, for example, a ferromagnetic material. The conductive layer 40 and the conductive layer 50 include, for example, the same material as the ferromagnetic layer 20.

The conductive layer 40 and the conductive layer 50 do not need to be ferromagnetic. When the conductive layer 40 or the conductive layer 50 does not contain a ferromagnetic material, a motion range of the magnetic domain wall DW is controlled by changing the current density of the current flowing through the magnetic domain wall motion layer 10. The current density of the current flowing in the magnetic domain wall motion layer 10 sharply decreases at a position overlapping the conductive layer 40 or the conductive layer 50 in the z direction. The moving speed of the magnetic domain wall DW is proportional to the current density. It is difficult for the magnetic domain wall DW to invade the first region A1 and the second region A2, in which the moving speed rapidly decreases.

Also, as shown in FIG. 4, for example, a width of the conductive layer 40 in the y direction may be wider than the width of the magnetic domain wall motion layer 10 in the y direction. Similarly, a width of the conductive layer 50 in the y direction may be wider than the width of the magnetic domain wall motion layer 10 in the y direction. With this configuration, a magnetic property distribution in the y direction in the magnetic domain wall motion layer 10 becomes uniform. When the magnetic property distribution in the y direction in the magnetic domain wall motion layer 10 becomes uniform, tilting of the magnetic domain wall DW in the y direction can be inhibited.

Shapes of the conductive layer 40 and the conductive layer 50 in a plan view in the z direction are not particularly limited. The shapes of the conductive layer 40 and the conductive layer 50 in a plan view in the z direction are, for example, rectangular, circular, elliptical, oval, or the like.

Directions of magnetization of each layer of the magnetic domain wall motion element 100 can be confirmed, for example, by measuring a magnetization curve. The magnetization curve can be measured using, for example, the magneto optical Kerr effect (MOKE). Measurement by MOKE is a measurement method performed by making linearly polarized light incident on a measurement target and using a magneto optical effect (magnetic Kerr effect) that causes rotation of a polarization direction thereof.

A periphery of the magnetic domain wall motion element 100 is covered by the insulating layer 90. The insulating layer 90 includes, for example, an insulating layer 91, an insulating layer 92, and an insulating layer 93.

The insulating layer 91, the insulating layer 92, and the insulating layer 93 are in different layers. The insulating layer 91 is, for example, in the same layer as the conductive layer 40 and the conductive layer 50. The insulating layer 91 is between the conductive layer 40 and the conductive layer 50. The insulating layer 92 is, for example, in the same layer as the wiring VL. The insulating layer 92 is in contact with a surface of the insulating layer 91 on a side opposite to the magnetic domain wall motion layer 10. The insulating layer 93 is, for example, in the same layer as the magnetic domain wall motion layer 10, the nonmagnetic layer 30, and the ferromagnetic layer 20.

The insulating layer 91, the insulating layer 92, and the insulating layer 93 may be made of the same material or may be made of different materials. The insulating layer 91 has higher thermal conductivity than the insulating layer 92, for example. The magnetic domain wall motion layer 10 tends to generate heat during operation. When a layer in contact with the magnetic domain wall motion layer 10 has higher thermal conductivity, heat generation of the magnetic domain wall motion element 100 can be efficiently inhibited. The insulating layer 91 is made of, for example, aluminum oxide. The insulating layer 92 is made of, for example, silicon oxide. The insulating layer 93 is made of, for example, silicon oxide or aluminum oxide.

The magnetic domain wall motion element 100 is formed through a process of laminating each layer and a process of processing a part of each layer into a predetermined shape. The lamination of each layer can be performed using a sputtering method, a chemical vapor deposition (CVD) method, an electron beam evaporation method (EB evaporation method), an atomic laser deposition method, or the like. Each layer can be processed using photolithography, etching (for example, Ar etching), and the like. The curved surfaces C1 and C2 of the magnetic domain wall motion layer 10 can be formed by forming a magnetic layer after processing the curved surfaces using photolithography and the like.

The magnetic domain wall motion element 100 according to the first embodiment can set a larger number of gradations as compared to a case in which the curved surface C1 is not formed on the first surface 10A of the magnetic domain wall motion layer 10.

The resistance value of the magnetic domain wall motion element 100 changes depending on a position of the magnetic domain wall DW at the position overlapping the ferromagnetic layer 20. When the magnetic domain wall motion layer 10 is curved, a moving distance of the magnetic domain wall DW increases than when the magnetic domain wall motion layer 10 is not curved. For that reason, a speed of resistance change of the magnetic domain wall motion element 100 becomes slower, and many gradations can be set within the same resistance change width. Also, in the case of reading the resistance value of the magnetic domain wall motion element 100 in analog form, the speed of resistance change becomes slower, and the resistance change of the magnetic domain wall motion element 100 can be read out accurately.

Further, in the magnetic domain wall motion element 100, the magnetic domain wall motion layer 10 is curved toward the conductive layer 40 and the conductive layer 50 side. For that reason, the heat generated in the magnetic domain wall motion layer 10 can be efficiently dissipated.

### Second Embodiment

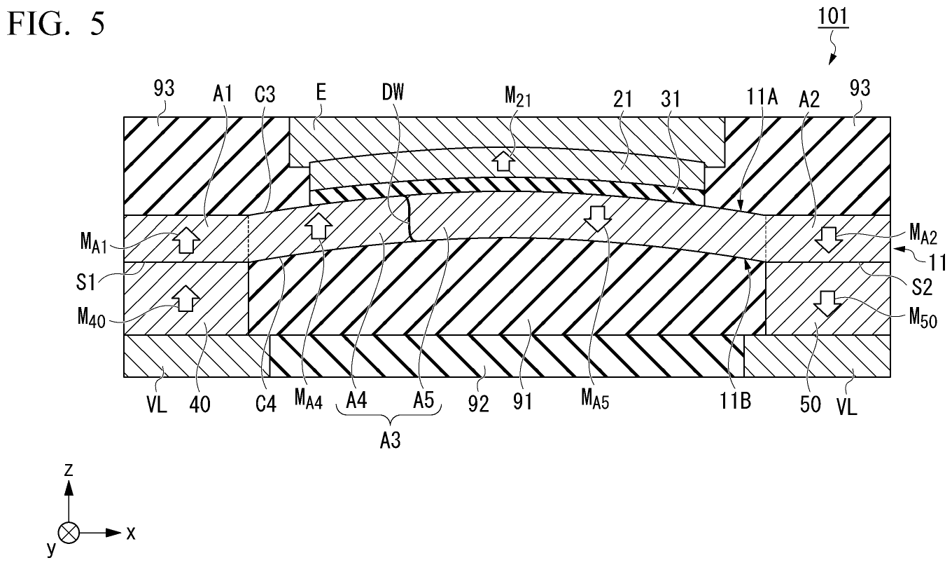

FIG. 5 is a cross-sectional view of a magnetic domain wall motion element 101 according to a second embodiment along the xz plane passing through a center of a magnetic domain wall motion layer 11 in the y direction. The magnetic domain wall motion element 101 according to the second embodiment is different from the magnetic domain wall motion element 100 according to the first embodiment in curving directions of a magnetic domain wall motion layer 11, a nonmagnetic layer 31, and a ferromagnetic layer 21. In the second embodiment, the same configurations as those in the first embodiment will be denoted by the same reference numerals, and the description thereof will be omitted.

The magnetic domain wall motion layer 11 is curved in the +z direction. The magnetic domain wall motion layer 11 is similar to the magnetic domain wall motion layer 10 except that the curving direction is different. In FIG. 5, the +z direction is a direction from the conductive layer 40 toward the magnetic domain wall motion layer 11, which is an example of a “first direction.” The center portion of the magnetic domain wall motion layer 11 in the x direction protrudes from the end portions in the +z direction of the z direction.

The magnetic domain wall motion layer 11 has a first surface 11A and a second surface 11B. The first surface 11A has a curved surface C3, and the second surface 11B has a curved surface C4. The curved surface C3 and the curved surface C4 are located at positions overlapping the ferromagnetic layer 21 when viewed in the z direction. The curved surface C3 and the curved surface C4 are both curved in the same direction, and each curved in the +z direction. The curved surface C3 and the curved surface C4 each have one inflection point in the xz cross-section.

The ferromagnetic layer 21 is curved in the +z direction. The ferromagnetic layer 21 is similar to the ferromagnetic layer 20 except that the curving direction is different. The ferromagnetic layer 21 is a magnetic material exhibiting magnetization M₂₁. The nonmagnetic layer 31 is curved in the +z direction. The nonmagnetic layer 31 is similar to the nonmagnetic layer 30 except that the curving direction is different.

The magnetic domain wall motion element 101 according to the second embodiment exhibits the same effects as the magnetic domain wall motion element 100, except that the curving direction of the magnetic domain wall motion layer 10 is different.

In addition, in the magnetic domain wall motion element 101, since the magnetic domain wall motion layer 10 is curved toward the side opposite to the conductive layer 40 and the conductive layer 50, the flow of the current between the conductive layer 40 or the conductive layer 50 and the magnetic domain wall motion layer 10 becomes smooth. As a result, local current concentration at an interface between the first region A1 and the third region A3 can be inhibited.

### Third Embodiment

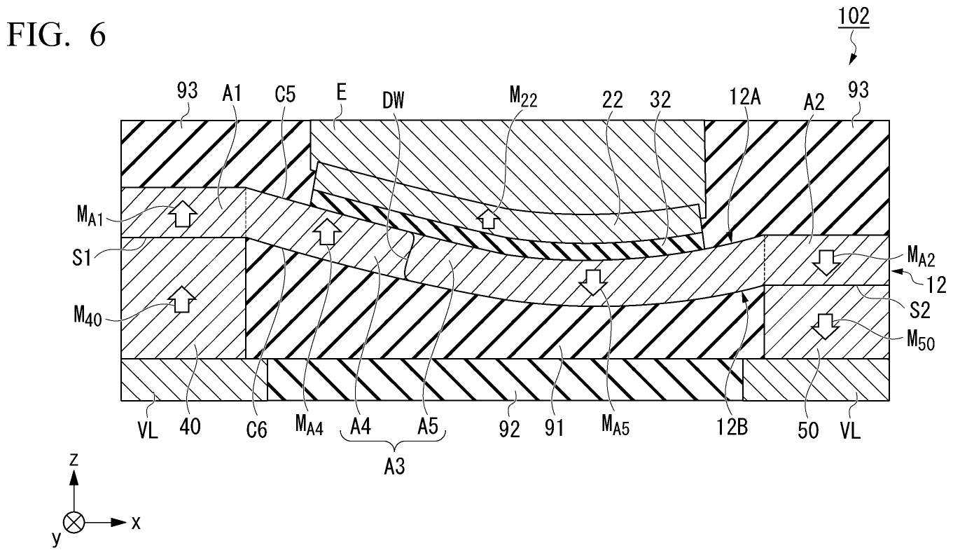

FIG. 6 is a cross-sectional view of a magnetic domain wall motion element 102 according to a third embodiment along the xz plane passing through a center of a magnetic domain wall motion layer 12 in the y direction. In the magnetic domain wall motion element 102 according to the third embodiment, positions of the connection surface S1 and the connection surface S2 in the z direction are different from each other. In the third embodiment, the same configurations as those in the first embodiment will be denoted by the same reference numerals, and the description thereof will be omitted.

The magnetic domain wall motion layer 12 is curved in the −z direction. The magnetic domain wall motion layer 12 is similar to the magnetic domain wall motion layer 10 except for its different shape.

The magnetic domain wall motion layer 12 has a first surface 12A and a second surface 12B. The first surface 12A has a curved surface C5, and the second surface 12B has a curved surface C6. The curved surface C5 and the curved surface C6 are located at positions overlapping the ferromagnetic layer 22 when viewed in the z direction. The curved surface C5 and the curved surface C6 are both curved in the same direction, and each curved in the −z direction.

The curved surface C5 and the curved surface C6 each have one inflection point in the xz cross-section. Positions of the inflection points of the curved surface C5 and the curved surface C6 are deviated from the center in the x direction. The inflection point of the curved surface C6 is located further in the −z direction than either the connection surface S1 or the connection surface S2. The inflection point of the curved surface C6 is located on the second direction side from both the connection surface S1 and the connection surface S2.

The ferromagnetic layer 22 is curved in the −z direction along the magnetic domain wall motion layer 12. The ferromagnetic layer 22 is similar to ferromagnetic layer 20 except for its different curved shape. The nonmagnetic layer 32 is curved along the magnetic domain wall motion layer 12 in the −z direction. The nonmagnetic layer 32 is similar to the nonmagnetic layer 30 except for its different curved shape.

In the magnetic domain wall motion element 102, since the positions of the connection surface S1 and the connection surface S2 in the z direction are different from each other, the moving distance of the magnetic domain wall DW can be increased. Accordingly, many gradations can be set within the same resistance change width of the magnetic domain wall motion element 102. Further, since the inflection point of the curved surface C6 is located closer to the conductive layer 40 and the conductive layer 50 side than the connection surfaces S1 and S2, the heat generated in the magnetic domain wall motion layer 10 can be efficiently dissipated.

### Fourth Embodiment

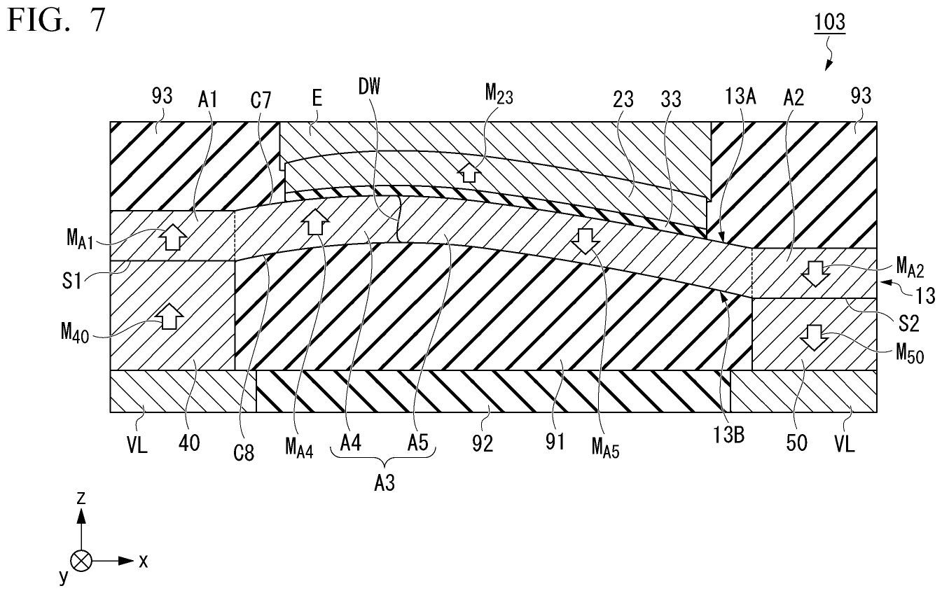

FIG. 7 is a cross-sectional view of a magnetic domain wall motion element 103 according to a fourth embodiment along the xz plane passing through a center of a magnetic domain wall motion layer 13 in the y direction. In the magnetic domain wall motion element 103 according to the fourth embodiment, positions of the connection surface S1 and the connection surface S2 in the z direction are different from each other. The magnetic domain wall motion element 103 corresponds to the third embodiment in that the positions of the connection surface S1 and the connection surface S2 in the z direction are different from each other. In the fourth embodiment, the same configurations as those in the first embodiment will be denoted the same reference numerals, and the description thereof will be omitted.

The magnetic domain wall motion element 103 shown in FIG. 7 includes a magnetic domain wall motion layer 13, a ferromagnetic layer 23, and a nonmagnetic layer 33. Each of the magnetic domain wall motion layer 13, the ferromagnetic layer 23, and the nonmagnetic layer 33 has the same configuration respectively as the magnetic domain wall motion layer 12, the ferromagnetic layer 22, and the nonmagnetic layer 32, except that the curving direction is different from that of the magnetic domain wall motion layer 12, the ferromagnetic layer 22, and the nonmagnetic layer 32.

The magnetic domain wall motion layer 13 has a first surface 13A and a second surface 13B. The first surface 13A has a curved surface C7, and the second surface 13B has a curved surface C8. The curved surface C7 and the curved surface C8 are located at positions overlapping the ferromagnetic layer 23 when viewed in the z direction. The curved surface C7 and the curved surface C8 are both curved in the same direction, and each curved in the +z direction.

The curved surface C7 and the curved surface C8 each have one inflection point in the xz cross-section. Positions of the inflection points of the curved surface C7 and the curved surface C8 are deviated from the center in the x direction. The inflection point of the curved surface C8 is located on the +z direction side from both the connection surface S1 and the connection surface S2. The inflection point of the curved surface C8 is located on the first direction side from both the connection surface S1 and the connection surface S2.

The magnetic domain wall motion element 103 according to the fourth embodiment corresponds to the magnetic domain wall motion element 102 according to the third embodiment in that the positions of the connection surface S1 and the connection surface S2 in the z direction are different from each other, and exhibits the same effects as the magnetic domain wall motion element 103 according to the third embodiment. In addition, the magnetic domain wall motion element 103 according to the fourth embodiment corresponds to the magnetic domain wall motion element 101 according to the second embodiment in that the magnetic domain wall motion layer 13 is curved toward the side opposite to the conductive layer 40 and the conductive layer 50, and exhibits the same effects as the magnetic domain wall motion element 101 according to the second embodiment.

### Fifth Embodiment

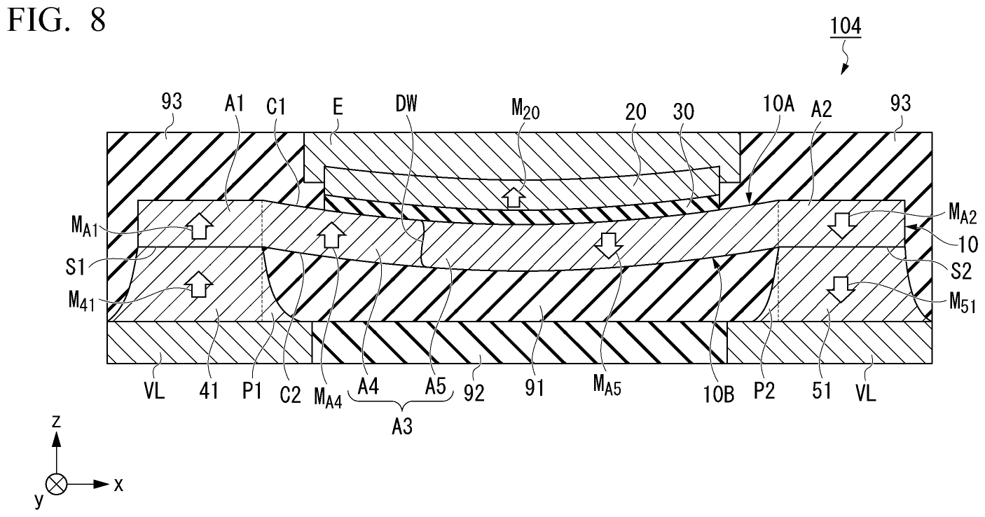

FIG. 8 is a cross-sectional view of a magnetic domain wall motion element 104 according to a fifth embodiment along the xz plane passing through a center of a magnetic domain wall motion layer 10 in the y direction. The magnetic domain wall motion element 104 according to the fifth embodiment is different from the magnetic domain wall motion element 100 according to the first embodiment in shapes of a conductive layer 41 and a conductive layer 51. In the fifth embodiment, the same configurations as those in the first embodiment will be denoted by the same reference numerals, and the description thereof will be omitted.

The conductive layer 41 has different circumferential lengths between an upper surface and a lower surface thereof in contact with the magnetic domain wall motion layer 10. The circumferential length of the conductive layer 41 increases from the upper surface to the lower surface. A side surface of the conductive layer 41 is inclined with respect to the z direction. The conductive layer 41 has a protruding portion P1 that protrudes from the connection surface S1 toward the conductive layer 51 side when viewed in the z direction. The protruding portion P1 protrudes below the third region A3 of the magnetic domain wall motion layer 10.

The conductive layer 51 has different circumferential lengths between an upper surface and a lower surface thereof in contact with the magnetic domain wall motion layer 10. The circumferential length of the conductive layer 51 increases from the upper surface to the lower surface. A side surface of the conductive layer 51 is inclined with respect to the z direction. The conductive layer 51 has a protruding portion P2 that protrudes from the connection surface S2 toward the conductive layer 41 side when viewed in the z direction. The protruding portion P2 protrudes below the third region A3 of the magnetic domain wall motion layer 10.

Since the magnetic domain wall motion element 104 has the protruding portion P1 and the protruding portion P2, the heat generated in the magnetic domain wall motion layer 10 can be efficiently dissipated.

### Sixth Embodiment

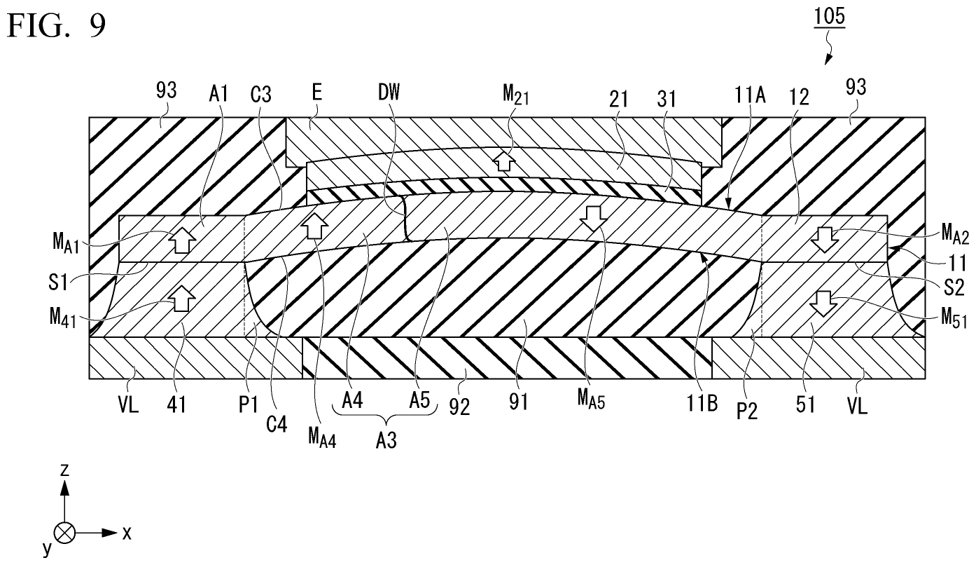

FIG. 9 is a cross-sectional view of a magnetic domain wall motion element 105 according to a sixth embodiment along the xz plane passing through a center of a magnetic domain wall motion layer 10 in the y direction. The magnetic domain wall motion element 105 according to the sixth embodiment is different from the magnetic domain wall motion element 101 according to the second embodiment in the shapes of the conductive layer 41 and the conductive layer 51. In the sixth embodiment, the same configurations as in the second embodiment and the fifth embodiment will be denoted by the same reference numerals, and the description thereof will be omitted.

The magnetic domain wall motion element 105 corresponds to the magnetic domain wall motion element 104 according to the fifth embodiment in that it has the protruding portion P1 and the protruding portion P2, and exhibits the same effects as the magnetic domain wall motion element 104 according to the fifth embodiment. In addition, the magnetic domain wall motion element 105 according to the sixth embodiment corresponds to the magnetic domain wall motion element 101 according to the second embodiment in that the magnetic domain wall motion layer 11 is curved toward the side opposite to the conductive layer 40 and the conductive layer 50, and exhibits the same effects as the magnetic domain wall motion element 101 according to the second embodiment.

### Seventh Embodiment

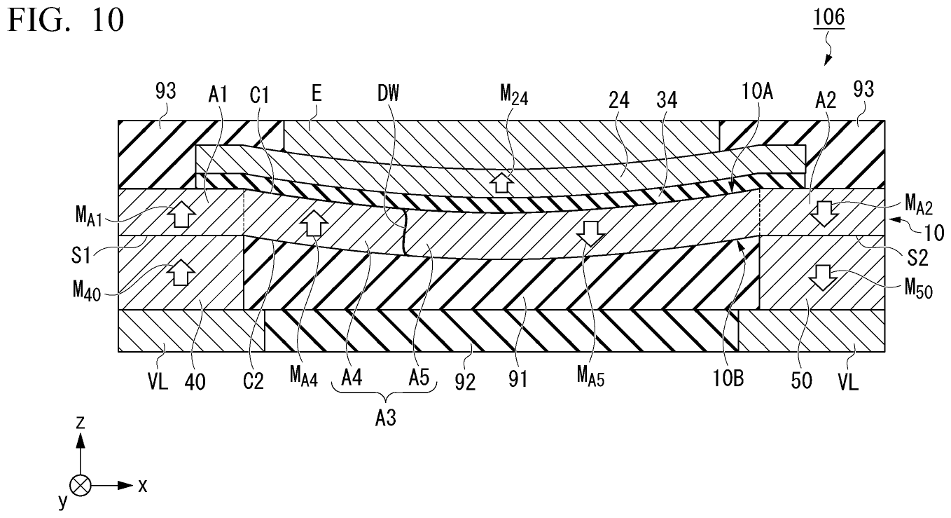

FIG. 10 is a cross-sectional view of a magnetic domain wall motion element 106 according to a seventh embodiment along the xz plane passing through a center of a magnetic domain wall motion layer 10 in the y direction. The magnetic domain wall motion element 106 according to the seventh embodiment is different from the magnetic domain wall motion element 100 according to the first embodiment in shapes of a ferromagnetic layer 24 and a nonmagnetic layer 34. In the seventh embodiment, the same configurations as those in the first embodiment will be denoted by the same reference numerals, and the description thereof will be omitted.

The ferromagnetic layer 24 partially overlaps the conductive layer 40 and the conductive layer 50 when viewed in the z direction. The ferromagnetic layer 24 is similar to the ferromagnetic layer 20 except for its shape. The ferromagnetic layer 24 is curved in the −z direction along the magnetic domain wall motion layer 10.

The nonmagnetic layer 34 partially overlaps the conductive layer 40 and the conductive layer 50 when viewed in the z direction. The nonmagnetic layer 34 is similar to the nonmagnetic layer 30 except for its shape. The nonmagnetic layer 34 is curved in the −z direction along the magnetic domain wall motion layer 10.

In the magnetic domain wall motion element 106, the ferromagnetic layer 24 covers the third region A3. A resistance value of the magnetic domain wall motion element 106 in the z direction changes depending on a difference between relative angles of magnetization of two ferromagnetic layers interposing the nonmagnetic layer 34. All of the motion of the magnetic domain wall DW in the third region A3 contributes to a resistance change of the magnetic domain wall motion element 106, and thus a resistance change width of the magnetic domain wall motion element 106 can be increased.

### Eighth Embodiment

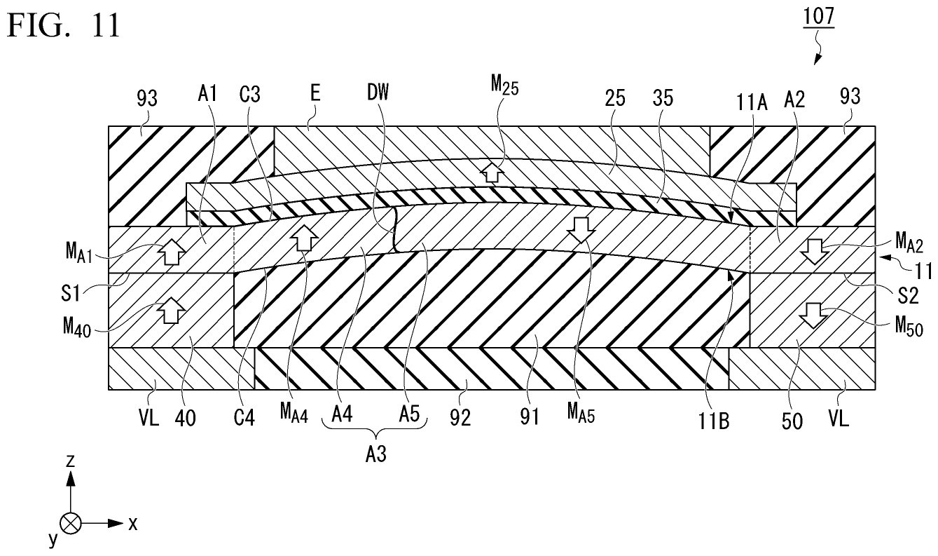

FIG. 11 is a cross-sectional view of a magnetic domain wall motion element 107 according to an eighth embodiment along the xz plane passing through a center of a magnetic domain wall motion layer 11 in the y direction. The magnetic domain wall motion element 107 according to the eighth embodiment is different from the magnetic domain wall motion element 101 according to the second embodiment in shapes of a ferromagnetic layer 25 and a nonmagnetic layer 35. In the eighth embodiment, the same configurations as those in the second embodiment will be denoted by the same reference numerals, and the description thereof will be omitted.

The ferromagnetic layer 25 partially overlaps the conductive layer 40 and the conductive layer 50 when viewed in the z direction. The ferromagnetic layer 25 is similar to the ferromagnetic layer 20 except for its shape. The ferromagnetic layer 25 is curved in the +z direction along the magnetic domain wall motion layer 11.

The nonmagnetic layer 35 partially overlaps the conductive layer 40 and the conductive layer 50 when viewed in the z direction. The nonmagnetic layer 35 is similar to the nonmagnetic layer 30 except for its shape. The nonmagnetic layer 35 is curved in the +z direction along the magnetic domain wall motion layer 11.

The magnetic domain wall motion element 107 according to the eighth embodiment exhibits the same effects as the magnetic domain wall motion element 106 according to the seventh embodiment. In addition, the magnetic domain wall motion element 107 according to the eighth embodiment exhibits the same effects as the magnetic domain wall motion element 101 according to the second embodiment.

### Ninth Embodiment

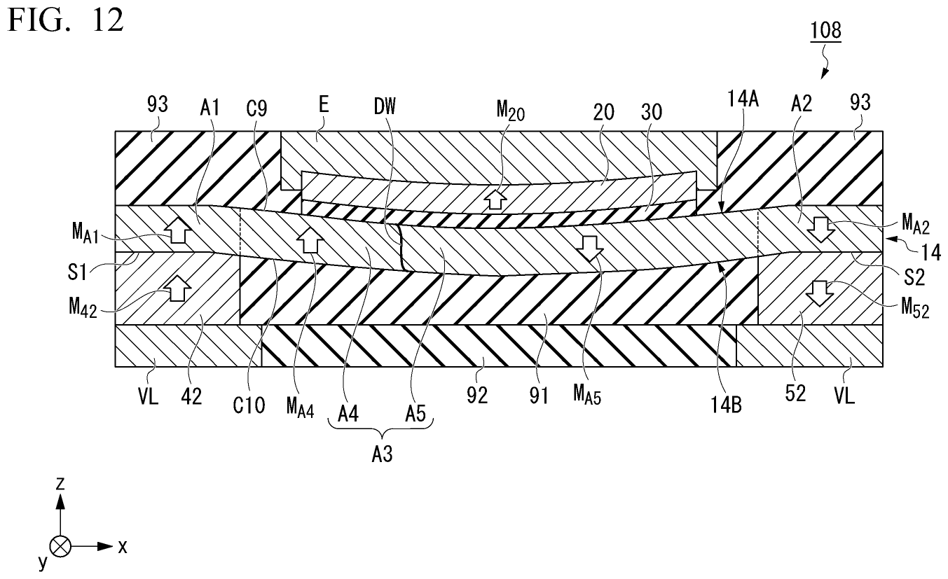

FIG. 12 is a cross-sectional view of a magnetic domain wall motion element 108 according to a ninth embodiment along the xz plane passing through a center of a magnetic domain wall motion layer 14 in the y direction. The magnetic domain wall motion element 108 according to the ninth embodiment is different from the magnetic domain wall motion element 100 according to the first embodiment in shapes of the magnetic domain wall motion layer 14, a conductive layer 42, and a conductive layer 52. In the ninth embodiment, the same configurations as those in the first embodiment will be denoted the same reference numerals, and the description thereof will be omitted.

The magnetic domain wall motion layer 14 has a curved surface C9 on a first surface 14A and a curved surface C10 on a second surface 14B. The curved surface C9 and the curved surface C10 reach points overlapping the conductive layer 42 and the conductive layer 52. Except for this point, the magnetic domain wall motion layer 14 has the same configuration as the magnetic domain wall motion layer 10.

In the conductive layer 42, a part of the connection surface S1 is inclined by the curved surface C10. Except for this point, the conductive layer 42 has the same configuration as the conductive layer 40. In the conductive layer 52, a part of the connection surface S2 is inclined by the curved surface C10. Except for this point, the conductive layer 52 has the same configuration as the conductive layer 50.

The magnetic domain wall motion element 108 according to the ninth embodiment exhibits the same effects as the magnetic domain wall motion element 100 according to the first embodiment.

### Tenth Embodiment

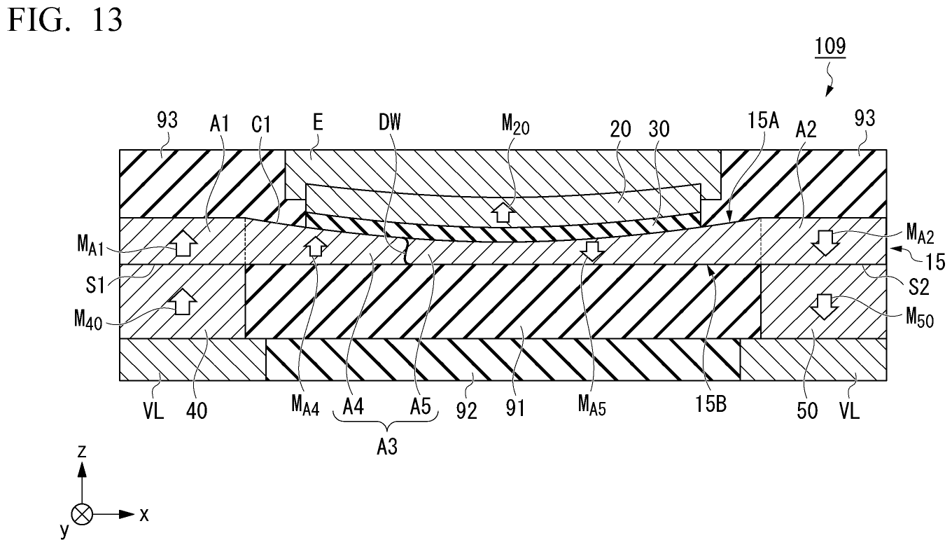

FIG. 13 is a cross-sectional view of a magnetic domain wall motion element 109 according to a tenth embodiment along the xz plane passing through a center of a magnetic domain wall motion layer 15 in the y direction. The magnetic domain wall motion element 109 according to the tenth embodiment is different from the magnetic domain wall motion element 100 according to the first embodiment in a shape of the magnetic domain wall motion layer 15. In the tenth embodiment, the same configurations as those in the first embodiment will be denoted the same reference numerals, and the description thereof will be omitted.

A first surface 15A of the magnetic domain wall motion layer 15 has a curved surface C1. A second surface 15B of the magnetic domain wall motion layer 15 is flat. No curved surface is formed on the second surface 15B. A thickness of the magnetic domain wall motion layer 15 varies depending on its position in the x direction. The magnetic domain wall motion layer 15 becomes thinner toward the center in the x direction.

The magnetic domain wall motion element 109 according to the tenth embodiment exhibits the same effects as the magnetic domain wall motion element 100 according to the first embodiment.

### Eleventh Embodiment

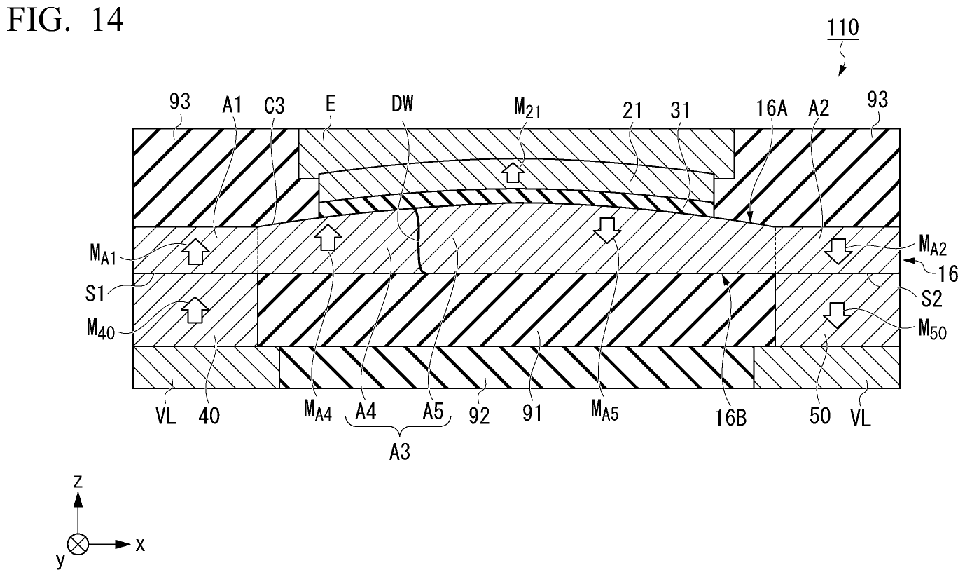

FIG. 14 is a cross-sectional view of a magnetic domain wall motion element 110 according to an eleventh embodiment along the xz plane passing through a center of a magnetic domain wall motion layer 16 in the y direction. The magnetic domain wall motion element 110 according to the eleventh embodiment is different from the magnetic domain wall motion element 101 according to the second embodiment in a shape of the magnetic domain wall motion layer 16. In the eleventh embodiment, the same configurations as those in the second embodiment will be denoted the same reference numerals, and the description thereof will be omitted.

A first surface 16A of the magnetic domain wall motion layer 16 has a curved surface C3. A second surface 16B of the magnetic domain wall motion layer 16 is flat. No curved surface is formed on the second surface 16B. A thickness of the magnetic domain wall motion layer 16 varies depending on its position in the x direction. The magnetic domain wall motion layer 16 becomes thicker toward the center in the x direction.

The magnetic domain wall motion element 110 according to the eleventh embodiment exhibits the same effects as the magnetic domain wall motion element 101 according to the second embodiment.

### Twelfth Embodiment

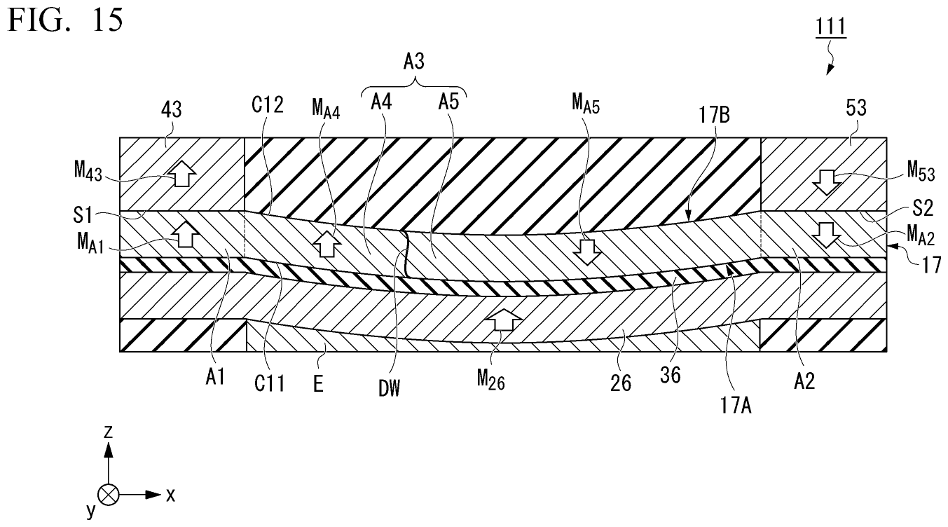

FIG. 15 is a cross-sectional view of a magnetic domain wall motion element 111 according to a twelfth embodiment along the xz plane passing through a center of a magnetic domain wall motion layer 17 in the y direction. In the twelfth embodiment, the same configurations as those in the first embodiment will be denoted the same reference numerals, and the description thereof will be omitted.

The magnetic domain wall motion element 111 includes the magnetic domain wall motion layer 17, a ferromagnetic layer 26, a nonmagnetic layer 36, a conductive layer 43, and a conductive layer 53. The magnetic domain wall motion element 111 is different from the above-described embodiments in that the ferromagnetic layer 26, the nonmagnetic layer 36, and the magnetic domain wall motion layer 17 are laminated in order. The magnetic domain wall motion element 111 has a bottom pin structure in which the ferromagnetic layer 26 is on the substrate Sub side. The conductive layer 43 and the conductive layer 53 are laminated on the magnetic domain wall motion layer 17.

The magnetic domain wall motion layer 17 has a curved surface C11 on a first surface 17A and a curved surface C12 on a second surface 17B. The curved surface C11 and the curved surface C12 are curved in the −z direction. In FIG. 15, the −z direction is a direction from the conductive layer 43 toward the magnetic domain wall motion layer 17, and is an example of the “first direction.” The magnetic domain wall motion layer 17 corresponds to the magnetic domain wall motion layer 11.

The ferromagnetic layer 26, the nonmagnetic layer 36, the conductive layer 43, and the conductive layer 53 correspond respectively to the ferromagnetic layer 21, the nonmagnetic layer 31, the conductive layer 40, and the conductive layer 50.

In the magnetic domain wall motion element 111 according to the twelfth embodiment, the magnetic domain wall motion layer 17 is curved toward a side opposite to the conductive layer 43 and the conductive layer 53, and exhibits the same effects as the magnetic domain wall motion element 101 according to the second embodiment.

### Thirteenth Embodiment

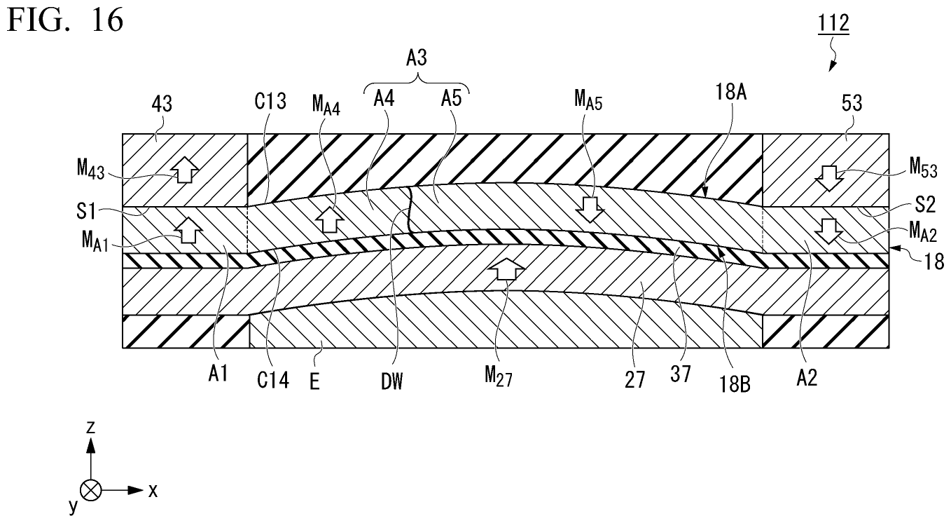

FIG. 16 is a cross-sectional view of a magnetic domain wall motion element 112 according to a thirteenth embodiment along the xz plane passing through a center of a magnetic domain wall motion layer 18 in the y direction. In the thirteenth embodiment, the same configurations as those in the twelfth embodiment will be denoted by the same reference numerals, and the description thereof will be omitted.

The magnetic domain wall motion element 112 includes a magnetic domain wall motion layer 18, a ferromagnetic layer 27, a nonmagnetic layer 37, the conductive layer 43, and the conductive layer 53. The magnetic domain wall motion element 112 is different from the magnetic domain wall motion element 111 according to the twelfth embodiment in a curving direction of the ferromagnetic layer 27, the nonmagnetic layer 37, and the magnetic domain wall motion layer 18. The magnetic domain wall motion element 112 has a bottom pin structure in which the ferromagnetic layer 27 is on the substrate Sub side.

The magnetic domain wall motion layer 18 has a curved surface C13 on a first surface 18A and a curved surface C14 on a second surface 18B. The curved surface C13 and the curved surface C14 are curved in the +z direction. In FIG. 16, the +z direction is a direction opposite to the direction from the conductive layer 43 toward the magnetic domain wall motion layer 18, and is an example of the “second direction.” The magnetic domain wall motion layer 18 corresponds to the magnetic domain wall motion layer 10.

The ferromagnetic layer 27, the nonmagnetic layer 37, the conductive layer 43, and the conductive layer 53 correspond respectively to the ferromagnetic layer 20, the nonmagnetic layer 30, the conductive layer 40, and the conductive layer 50.

In the magnetic domain wall motion element 112 according to the thirteenth embodiment, the magnetic domain wall motion layer 18 is curved toward the conductive layer 43 and the conductive layer 53, and exhibits the same effects as the magnetic domain wall motion element 100 according to the first embodiment.

### Fourteenth Embodiment

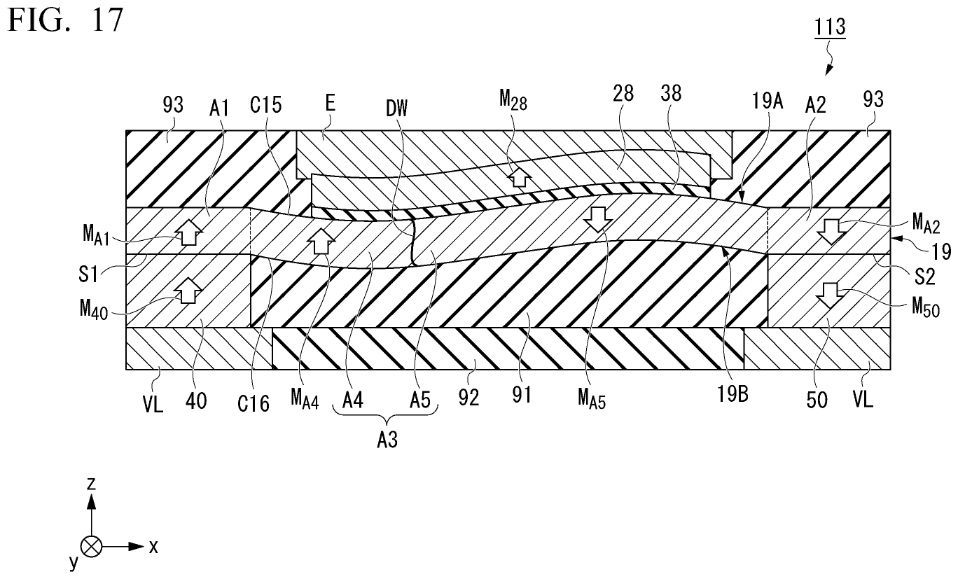

FIG. 17 is a cross-sectional view of a magnetic domain wall motion element 113 according to a fourteenth embodiment along the xz plane passing through a center of a magnetic domain wall motion layer 19 in the y direction. In the fourteenth embodiment, the same configurations as those in the first embodiment will be denoted by the same reference numerals, and the description thereof will be omitted.

The magnetic domain wall motion element 113 includes the magnetic domain wall motion layer 19, a ferromagnetic layer 28, a nonmagnetic layer 38, the conductive layer 40, and the conductive layer 50.

The magnetic domain wall motion layer 19, the ferromagnetic layer 28, and the nonmagnetic layer 38 correspond respectively to the magnetic domain wall motion layer 10, the ferromagnetic layer 20, and the nonmagnetic layer 30. The magnetic domain wall motion layer 19, the ferromagnetic layer 28, and the nonmagnetic layer 38 are each wavy.

The magnetic domain wall motion layer 19 has a curved surface C15 on a first surface 19A and a curved surface C16 on a second surface 19B. The curved surface C15 and the curved surface C16 each have two inflection points in the xz cross-section and are wavy. Although FIG. 17 shows an example in which the curved surface C15 and the curved surface C16 have two inflection points in the xz cross-section, the number of inflection points may be greater than two.

The magnetic domain wall motion element 113 according to the fourteenth embodiment can increase the number of gradations as compared to a case in which the curved surface C15 is not formed on the first surface 19A of the magnetic domain wall motion layer 19.

Although the preferred embodiments of the present invention have been described in detail above, the present invention is not limited to these embodiments. For example, the featured configurations of the respective embodiments may be combined together, or parts may be changed within a range not changing the gist of the invention.

### REFERENCE SIGNS LIST

10, 11, 12, 13, 14, 15, 16, 17, 18, 19 Magnetic domain wall motion layer
10A, 11A, 12A, 13A, 14A, 15A, 16A, 17A, 18A, 19A First side
10B, 11B, 12B, 13B, 14B, 15B, 16B, 17B, 18B, 19B Second side
20, 21, 22, 23, 24, 25, 26, 27, 28 Ferromagnetic layer
30, 31, 32, 33, 34, 35, 36, 37, 38 Nonmagnetic layer
40, 41, 42, 43 Conductive layer
50, 51, 52, 53 Conductive layer
90, 91, 92, 93 Insulating layer
100, 101, 102, 103, 104, 105, 106, 107, 108, 109, 110, 111, 112, 113 Magnetic domain wall motion element
200 Magnetic array
C1, C2, C3, C4, C5, C6, C7, C8, C9, C10, C11, C12, C13, C14, C15, C16 Curved surface
DW Magnetic domain wall
S1, S2 Connection surface

1. A magnetic domain wall motion element comprising:
a magnetic domain wall motion layer in which a magnetic domain wall is formed;
a ferromagnetic layer; and
a nonmagnetic layer interposed between the magnetic domain wall motion layer and the ferromagnetic layer,
wherein at least a portion of a first surface of the magnetic domain wall motion layer on a side closer to the ferromagnetic layer, at a position overlapping the ferromagnetic layer in a plan view in a laminating direction, is curved.

2. The magnetic domain wall motion element according to claim 1, wherein at least a portion of a second surface of the magnetic domain wall motion layer on a side opposite to the first surface, at a position overlapping with the ferromagnetic layer in a plan view in the laminating direction, is curved in the same direction as the first surface.

3. The magnetic domain wall motion element according to claim 1, wherein the curved surface of the first surface is curved in one direction.

4. The magnetic domain wall motion element according to claim 3 further comprising:
a first conductive layer and a second conductive layer each connected to the magnetic domain wall motion layer,
wherein the curved surface of the first surface is curved in a first direction when a direction from the first conductive layer toward the magnetic domain wall motion layer in the laminating direction is defined as the first direction.

5. The magnetic domain wall motion element according to claim 3 further comprising:
a first conductive layer and a second conductive layer each connected to the magnetic domain wall motion layer,
wherein the curved surface of the first surface is curved in a second direction when a direction from the first conductive layer toward the magnetic domain wall motion layer in the laminating direction is defined as a first direction and a direction opposite to the first direction is defined as the second direction.

6. The magnetic domain wall motion element according to claim 1 further comprising:
a first conductive layer and a second conductive layer each connected to the magnetic domain wall motion layer,
wherein a first connection surface between the first conductive layer and the magnetic domain wall motion layer is at a different position in the laminating direction from a second connection surface between the second conductive layer and the magnetic domain wall motion layer.

7. The magnetic domain wall motion element according to claim 6,
wherein a second surface of the magnetic domain wall motion layer on the side opposite to the first surface includes the first connection surface, the second connection surface, and the curved surface, and when a direction from the first conductive layer toward the magnetic domain wall motion layer in the laminating direction is defined as a first direction, an inflection point of the curved surface of the second surface is located on the first direction side from positions of the first connection surface and the second connection surface in the laminating direction.

8. The magnetic domain wall motion element according to claim 6,
wherein a second surface of the magnetic domain wall motion layer on the side opposite to the first surface includes the first connection surface, the second connection surface, and the curved surface, and
when a direction from the first conductive layer to the magnetic domain wall motion layer in the laminating direction is defined as a first direction and a direction opposite to the first direction is defined as a second direction, an inflection point of the curved surface of the second surface is located on the second direction side from positions of the first connection surface and the second connection surface in the laminating direction.

9. The magnetic domain wall motion element according to claim 1 further comprising:
a first conductive layer and a second conductive layer each connected to the magnetic domain wall motion layer,
wherein a part of the first conductive layer protrudes toward the second conductive layer from a first connection surface between the first conductive layer and the magnetic domain wall motion layer when viewed in the laminating direction.

10. The magnetic domain wall motion element according to claim 1 comprising:
a first conductive layer and a second conductive layer each connected to the magnetic domain wall motion layer;
a first insulating layer located between the first conductive layer and the second conductive layer; and
a second insulating layer in contact with a surface of the first insulating layer on a side opposite to a surface in contact with the magnetic domain wall motion layer,
wherein the first insulating layer has higher thermal conductivity than the second insulating layer.

11. A magnetic array comprising a plurality of magnetic domain wall motion elements according to claim 1.
